(19) United States
(12) Patent Application Publication
(10) Pub. No.: US 2013/0097474 A1
(43) Pub. Date: Apr. 18, 2013

(54) APPARATUS AND METHOD FOR TRANSMITTING/RECEIVING FORWARD ERROR CORRECTION PACKET IN MOBILE COMMUNICATION SYSTEM

(71) Applicant: SAMSUNG ELECTRONICS CO. LTD., Suwon-si (KR)

(72) Inventors: Sung-Hee HWANG, Suwon-si (KR); Hyun-Koo YANG, Seoul (KR)

(73) Assignee: SAMSUNG ELECTRONICS CO. LTD., Suwon-si (KR)

(21) Appl. No.: 13/651,917

(22) Filed: Oct. 15, 2012

(30) Foreign Application Priority Data
Oct. 13, 2011 (KR) 10-2011-0104506

(51) Int. Cl. H03M 13/13

(52) U.S. Cl. 714/776; 714/E11.032

(57) ABSTRACT

An apparatus and method for transmitting/receiving a Forward Error Correction (FEC) packet in a mobile communication system are provided. In the FEC packet transmission method, an FEC packet transmission apparatus transmits an FEC delivery block to an FEC packet reception apparatus, wherein the FEC delivery block includes K source payloads and P parity payloads, each of the K source payloads and the P parity payloads includes a payload header, and each of the payload headers includes length information related to a length of a related payload.

### PRIORITY

This application claims the benefit under 35 U.S.C. §119(a) of a Korean patent application filed on Oct. 13, 2011 in the Korean Intellectual Property Office and assigned Serial No. 10-2011-0104506, the entire disclosure of which is hereby incorporated by reference.

### BACKGROUND OF THE INVENTION

1. Field of the Invention

The present invention relates to an apparatus and method for transmitting/receiving a packet in a mobile communication system. More particularly, the present invention relates to an apparatus and method for transmitting/receiving a Forward Error Correction (FEC) packet in a mobile communication system.

2. Description of the Related Art

According to diversification of contents and increases in large-capacity contents, such as High Definition (HD) contents and Ultra High Definition (UHD) contents on a mobile communication system, data congestion has become a serious concern. Due to such data congestion, contents transmitted by a signal transmission device may not be completely transferred to a signal reception device, and some of the contents may be lost en route.

In general, because data is transmitted on a packet basis, data is lost on a transport packet basis. Accordingly, if the transport packet is lost on a network, the signal reception device cannot receive the lost transport packet, and thus is unaware of data associated with the lost transport packet. As a result, user inconvenience may occur in various forms, such as audio signal quality deterioration, video picture quality deterioration, video picture break, caption omission, file loss, and the like.

In a technology for reconstructing lost data on a network, a parity block by an FEC encoding may be added to a source block including a predetermined number of packets and may then be transmitted. In general, a size or length of data transmitted within the packet (i.e., source payload) may have a fixed packet size or a variable packet size. For example, a Moving Picture Experts Group2 (MPEG2) Transport Stream (TS) has a fixed packet size of 188 bytes including a header of 4 bytes and a payload of 184 bytes. However, a Real-Time Transport Protocol (RTP) packet size or a MPEG Media Transport packet size is not always fixed.

If a variable packet size is applied, the signal transmission device may generate a source block by adding padding data to ensure uniformity of transmitted packet data and then perform an FEC encoding operation on the generated source block.

In this case, upon repairing a packet which has been lost on a network (e.g., channel) according to an FEC decoding operation, an FEC decoder should detect an accurate size of a packet before padding data is included since the FEC decoder repairs a source block (i.e., repairs the source block including the padding data).

Therefore, a need exists for a method for accurately notifying an FEC decoder of a size of a packet before padding data is included. That is, there is a need for an FEC packet transmission/reception method for notifying the size of the packet before the padding data is included in a Moving Picture Experts Group (MPEG) Media Transport (MMT) system supporting a variable packet size.

### SUMMARY OF THE INVENTION

Aspects of the present invention are to address at least the above-mentioned problems and/or disadvantages and to provide at least the advantages described below. Accordingly, an aspect of the present invention is to provide an apparatus and method for transmitting/receiving a Forward Error Correction (FEC) packet in a mobile communication system.

Another aspect of the present invention is to provide an FEC packet transmission/reception apparatus and method for notifying a size of data before padding data is included in a mobile communication system.

Further another aspect of the present invention is to provide an FEC packet transmission/reception apparatus and method for notifying a size of data before padding data is included through Application Layer FEC (AL-FEC) signaling information in a mobile communication system.

Still another aspect of the present invention is to provide an FEC packet transmission/reception apparatus and method for generating a source block corresponding to an Information Block Generation (IBG) mode in a mobile communication system.

Still another aspect of the present invention is to provide an FEC packet transmission/reception apparatus and method for notifying a size of a payload of a source block generated corresponding to an IBG mode in a mobile communication system.

In accordance with an aspect of the present invention, a method for transmitting a FEC packet by an FEC packet transmission apparatus in a mobile communication system is provided. The method includes transmitting an FEC delivery block to an FEC packet reception apparatus, wherein the FEC delivery block includes K source payloads and P parity payloads, each of the K source payloads and the P parity payloads includes a payload header, and each of the payload headers includes length information related to a length of a related payload.

In accordance with another aspect of the present invention, a method for receiving a FEC packet by an FEC packet reception apparatus in a mobile communication system is provided. The method includes receiving an FEC delivery block from an FEC packet transmission apparatus, wherein the FEC delivery block includes K source payloads and P parity payloads, each of the K source payloads and the P parity payloads includes a payload header, and each of the payload headers includes length information related to a length of a related payload.

In accordance with further another aspect of the present invention, a FEC packet transmission apparatus in a mobile communication system is provided. The FEC packet transmission apparatus includes a transmitter for transmitting an FEC delivery block to an FEC packet reception apparatus, wherein the FEC delivery block includes K source payloads and P parity payloads, each of the K source payloads and the P parity payloads includes a payload header, and each of the payload headers includes length information related to a length of a related payload.

In accordance with still another aspect of the present invention, an FEC packet reception apparatus in a mobile communication system is provided. The FEC packet reception apparatus includes a receiver for receiving an FEC delivery block from an FEC packet transmission apparatus, wherein the FEC delivery block includes K source payloads and P parity payloads, each of the K source payloads and the P parity payloads includes a payload header, and each of the payload headers includes length information related to a length of a related payload.

Other aspects, advantages, and salient features of the invention will become apparent to those skilled in the art from the following detailed description, which, taken in conjunction with the annexed drawings, discloses exemplary embodiments of the invention.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIGS. 1A and 1B illustrate a network topology and a data flow in a Moving Picture Experts Group (MPEG) Media Transport (MMT) system according to an exemplary embodiment of the present invention;

FIG. 2 illustrates a process for generating a source block by a Forward Error Correction (FEC) packet transmission apparatus of which an operation mode is an Information Block Generation (IBG)_mode1 in an MMT system according to an exemplary embodiment of the present invention;

FIG. 3 illustrates a process for generating a source block by an FEC packet transmission apparatus of which an operation mode is an IBG_mode2 in an MMT system according to an exemplary embodiment of the present invention;

FIG. 4 illustrates offset information of each payload included in a two-dimensional array, for example the two-dimensional array as shown in FIG. 3, according to an exemplary embodiment of the present invention;

FIG. 5 schematically illustrates an operation of an FEC packet transmission apparatus of an MMT system according to an exemplary embodiment of the present invention;

FIG. 6 schematically illustrates an operation of an FEC packet reception apparatus of an MMT system according to an exemplary embodiment of the present invention;

FIG. 7 schematically illustrates a structure of an MMT system and a delivery function layer according to an exemplary embodiment of the present invention;

FIG. 8 schematically illustrates an Application Layer (AL)-FEC source block encoding process performed by an FEC packet transmission apparatus of an MMT system according to an exemplary embodiment of the present invention;

FIG. 9 schematically illustrates a structure of a virtual length block and a parity data block generated by an FEC packet transmission apparatus of an MMT system according to an exemplary embodiment of the present invention;

FIG. 10 schematically illustrates a structure of an information block and a parity block generated by an FEC packet transmission apparatus of an MMT system according to an exemplary embodiment of the present invention;

FIG. 11 schematically illustrates a structure of a Radio Frequency (RF) frame, which uses a Reed-Solomon (RS) (240,200) code over a Galois Field (GF) (2̂8) if m is 8 (m=8), generated by an FEC packet transmission apparatus of an MMT system according to an exemplary embodiment of the present invention;

FIG. 12 schematically illustrates a structure of a Low Density Parity Check (LDPC) frame, which uses a (m×(K+P), m×K) LDPC code over a GF (2̂8), generated by an FEC packet transmission apparatus of an MMT system according to an exemplary embodiment of the present invention;

FIG. 13 is a block diagram schematically illustrating an internal structure of an FEC packet transmission apparatus in an MMT system according to an exemplary embodiment of the present invention; and

FIG. 14 is a block diagram schematically illustrating an internal structure of an FEC packet reception apparatus in an MMT system according to an exemplary embodiment of the present invention.

Throughout the drawings, it should be noted that like reference numbers are used to depict the same elements, features and structures.

### DETAILED DESCRIPTION OF EXEMPLARY EMBODIMENTS

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and words used in the following description and claims are not limited to the bibliographical meanings, but, are merely used by the inventor to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

An exemplary embodiment of the present invention proposes an apparatus and method for transmitting/receiving a Forward Error Correction (FEC) packet in a mobile communication system.

Another exemplary embodiment of the present invention proposes an FEC packet transmission/reception apparatus and method for notifying a size of data before padding data is included in a mobile communication system.

Further another exemplary embodiment of the present invention proposes an FEC packet transmission/reception apparatus and method for notifying a size of data before padding data is included through Application Layer FEC (AL-FEC) signaling information in a mobile communication system.

Still another exemplary embodiment of the present invention proposes an FEC packet transmission/reception apparatus and method for generating a source block corresponding to an Information Block Generation (IBG) mode in a mobile communication system.

Still another exemplary embodiment of the present invention proposes an FEC packet transmission/reception apparatus and method for notifying a size of a payload of a source block generated corresponding to an IBG mode in a mobile communication system.

Exemplary embodiments of the present invention will be described below with reference to a mobile communication system, for example, an Evolved Packet System (EPS). However, it will be understood by those of ordinary skill in the art that the mobile communication system may be any one of a Long-Term Evolution (LTE) mobile communication system, a Long-Term Evolution Advanced (LTE-A) mobile communication system, an Institute of Electrical and Electronics Engineers (IEEE) 802.16m mobile communication system, as well as the EPS and the like.

For convenience, the following terminologies are defined.

### (1) FEC Code

The FEC code represents an error correction code used for correcting an error symbol or an erasure symbol.

### (2) FEC Frame

The FEC frame represents a codeword which is generated by encoding an information word using an FEC encoding scheme. The FEC frame includes an information part and a parity part. The parity part is referred to as a repair part.

### (3) Symbol

The symbol represents a unit of data, and has a symbol size in bits or bytes.

### (4) Source Symbol

The source symbol represents an unprotected data symbol, and the unprotected data symbol represents an original data symbol which may not be protected.

### (5) Information Symbol

The information symbol represents one of an unprotected data symbol and a padding symbol included in an information part included in an FEC frame.

### (6) Codeword

The codeword represents an FEC frame which is generated by encoding an information symbol using an FEC encoding scheme.

### (7) Parity Symbol

The parity symbol is generated using an FEC encoding scheme based on an information symbol. The parity symbol is included in an FEC frame.

### (8) Packet

The Packet represents a transmission unit of data including a header and a payload.

### (9) Payload

The payload is included in a packet and represents a part of a user data to be transmitted in a transmitter.

### (10) Packet Header

The packet header represents a header included in a packet.

### (11) Source Payload

The source payload represents a payload including source symbols, and a unit which is protected by an FEC scheme.

If a D2 header is protected using an FEC scheme, the source payload is an MMT transport packet. If the D2 header is not protected using the FEC scheme, the source payload is an MMT transport format. For convenience, an FEC scheme for protecting the D2 header is called as D2-FEC scheme, and an FEC scheme for not protecting the D2 header is called as D1-FEC scheme. The D2-FEC scheme and the D1-FEC scheme will be described.

Firstly, the D2-FEC scheme will be described.

In the D2-FEC scheme, a Moving Picture Experts Group (MPEG) Media Transport (MMT) transport packet is used for interfacing with an underlying layer.

In the D2-FEC scheme, a source payload may be an MMT transport packet, and the MMT transport packet includes a D2 header and an MMT payload (source payload=MMT transport packet (=D2 header+MMT payload format)).

The source payload and an FEC in-band signal included in an MMT transport packet are transmitted after FEC protection. That is, the MMT transport packet is modified to include the FEC in-band signal. So, the MMT transport packet after the FEC protection includes a D2 header, an FEC in-band signal and an MMT payload format (MMT transport packet=D2 header+FEC in-band signal+MMT payload format). The FEC in-band signal is located behind the D2 header or the MMT payload format.

The MMT transport packet is expressed below:

MMT transport packet=D2 header+(D1 header)+FEC in-band signal+parity payload

Secondly, the D1-FEC scheme will be described.

In the D1-FEC scheme, an MMT payload format is used for interfacing with a D2 layer.

In the D1-FEC scheme, a source payload may be an MMT payload format, and the payload format includes a D1 header and a payload (source payload=MMT payload format (=D1 header+payload)).

The source payload and an FEC in-band signal included in an MMT payload format are transmitted to a D2 layer or an application protocol layer, i.e., a Real Time Protocol (RTP) layer after FEC protection. That is, the MMT payload format is modified to include the FEC in-band signal. So, the MMT payload format after the FEC protection includes a D1 header, an FEC in-band signal and a payload (MMT payload format=D1 header+FEC in-band signal+payload). The FEC in-band signal is located behind the D1 header or the payload.

The MMT payload format is expressed below:

MMT payload format=D1 header+FEC in-band signal+parity payload

### (12) Information Payload

The information payload represents a payload including information symbols.

### (13) Parity Payload

The parity payload represents a payload including parity symbols.

### (14) Source Block

The source block includes at least one source payload, for example, K source payloads. The source block may be converted into an information block for FEC protection.

### (15) Information Block

The information block includes at least one information payload.

More specifically, the information block includes at least one information payload which is generated by converting a source block. The number of information payloads included in the information block may be changed according to an Information Block Generation (IBG) mode. For example, if the IBG mode is one of an IBG_mode0 and an IBG_mode1, the number of information payloads included in the information block may be equal to the number of source payloads included in the source block K. The number of information payloads included in the information block may not be equal to K if the IBG mode is not the IBG_mode0 or the IBG_mode1, that is, if the IBG mode is the IBG_mode2. The IBG_mode0, the IBG_mode1, and the IBG_mode2 will be described below.

Firstly, the IBG_mode0 will be described.

The IBG_mode0 represents an IBG mode which is applied if lengths of source payloads are the same, that is, a length of a source payload is fixed and a source block is identical to an information block.

Secondly, the IBG_mode1 represents an IBG mode that applies if a length of a source payload is variable. In the IBG_mode1, information blocks having sizes that are the same are generated by adding padding data to source payloads respectively. In the IBG_mode1, the number of source payloads included in a source block is equal to the number of information payloads included in an information block. In the IBG_mode1, the length of the source payload is variable, so virtual length information is needed for each of the source payloads. The IBG_mode1 will be described below.

Thirdly, the IBG_mode2 represents an IBG mode that applies if a length of a source payload is variable. In the IBG_mode2, information blocks having sizes that are the same are generated by adding padding data to source payloads respectively. In the IBG_mode2, the number of source payloads included in a source block may not be equal to the number of information payloads included in an information block. In the IBG_mode2, the length of the source payload is variable, so virtual length information is needed for each of the source payloads. The IBG_mode2 will be described below.

### (16) Repair Block

The repair block includes at least one repair payload, for example, P repair payloads. The repair block is referred to as a parity block.

### (17) FEC Block

The FEC block includes at least one codeword or at least one payload including an information block and a parity block.

### (18) FEC Delivery Block

The FEC delivery block includes at least one payload including a source block and a repair block.

### (19) FEC Packet

The FEC packet represents a packet used for transmitting an FEC block.

### (20) Source Packet

The source packet represents a packet used for transmitting a source block.

### (21) Parity Packet

The parity packet represents a packet used for transmitting a repair block.

### (22) FEC Packet Block

The FEC packet block includes at least one packet used for transmitting an FEC delivery block.

### (23) MMT Package

The MMT package includes at least one MMT asset. There are various types of MMT assets, for example, a video asset, an audio asset, a widget asset, and the like.

### (24) MMT Asset

The MMT asset consists of at least one Media Processing Unit (MPU). The MPU is converted into at least one MMT payload format by packetizing the MPU according to a size of the MPU. That is, according to a size of a Maximum Transport Unit (MTU), the MPU is converted into one MMT payload, or a plurality of MMT payloads, which are generated by fragmenting the MPU, or one MMT payload, including a plurality of MPUs, which is generated by aggregating the plurality of MPUs.

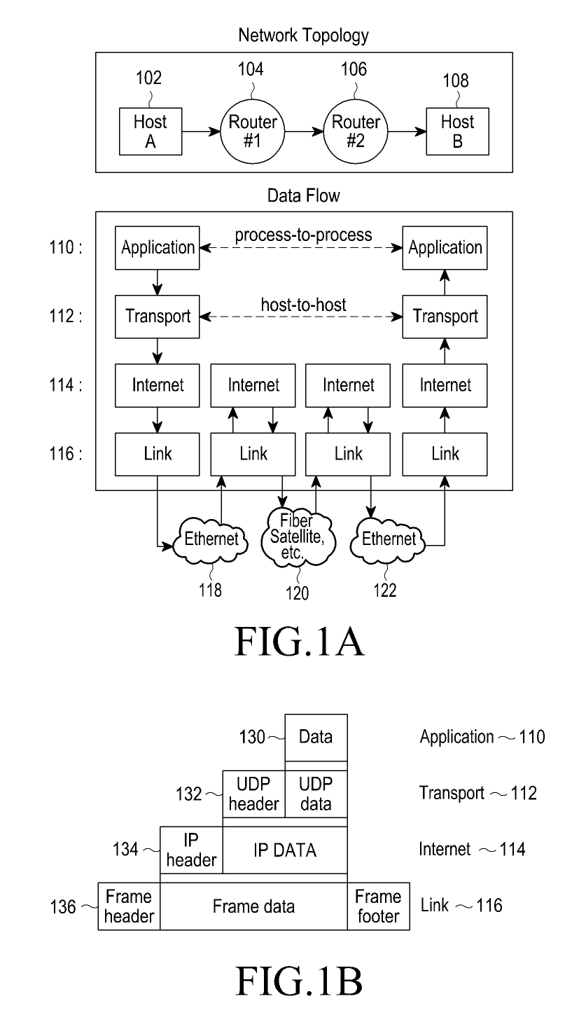

FIGS. 1A and 1B illustrate a network topology and a data flow in an MMT system according to an exemplary embodiment of the present invention.

Referring to FIG. 1A, the network topology includes a host A 102 operating as a signal transmission device and a host B 108 operating as a signal reception device. The host A 102 and the host B 108 are connected through one or more routers 104 and 106. The host A 102 and the host B 108 are connected with the routers 104 and 106 through Ethernets 118 and 122, and the routers 104 and 106 may be connected to each other through an optical fiber, satellite communication, or other available means 120. A data flow between the host A 102 and the host B 108 is generated through a link layer 116, an internet layer 114, a transport layer 112, and an application layer 110.

Referring to FIG. 1B, the application layer 110 generates data 130 desired to be transmitted, through an Application Layer FEC (AL-FEC). The data 130 may be RTP packet data fragmented from data compressed by an Audio/Video (AV) codec stage by using an RTP or MMT packet data according to MMT. The data 130 is converted to a User Datagram Protocol (UDP) packet 132 in which a UDP header is inserted by the transport layer 112 as an example. The internet layer 114 adds an Internet Protocol (IP) header to the UDP packet 132 to generate the IP packet 134, and the link layer 116 adds a frame header and a frame footer as necessary to the IP packet 134 to configure the frame 136 desired to be transmitted.

If compression on a frame basis is applied to the MMT system, the frame is fragmented into a plurality of packets having the same length, and it is required to pad only a last packet. However, if the frame is fragmented into a plurality of slices including video packets and encoded on a slice basis, respective slices may have different sizes, so that a relatively large amount of padding is generated. More particularly, if various types of packets such as a video packet, an audio packet, a text packet and the like are transmitted to the same stream and an AL-FEC encoding scheme is applied, different types of packets have different sizes, so that a large amount of padding may be generated. Further, in a scalable video encoding, sizes of packets may be different from each layer, so that a large amount of padding is generated.

In exemplary embodiments of the present invention described below, if an amount of data transmitted through a transport protocol is variable, that is, if packets with variable packet sizes are transmitted/received, an efficient AL-FEC encoding method is proposed.

Meanwhile, IBG modes on which the FEC packet transmission apparatus generates a source block used for FEC encoding include an IBG_mode0, an IBG_mode1, and an IBG_mode2.

As described above, the IBG_mode0 represents an IBG mode which is applied if lengths of source payloads are the same, that is, a length of a source payload is fixed and a source block is identical to an information block.

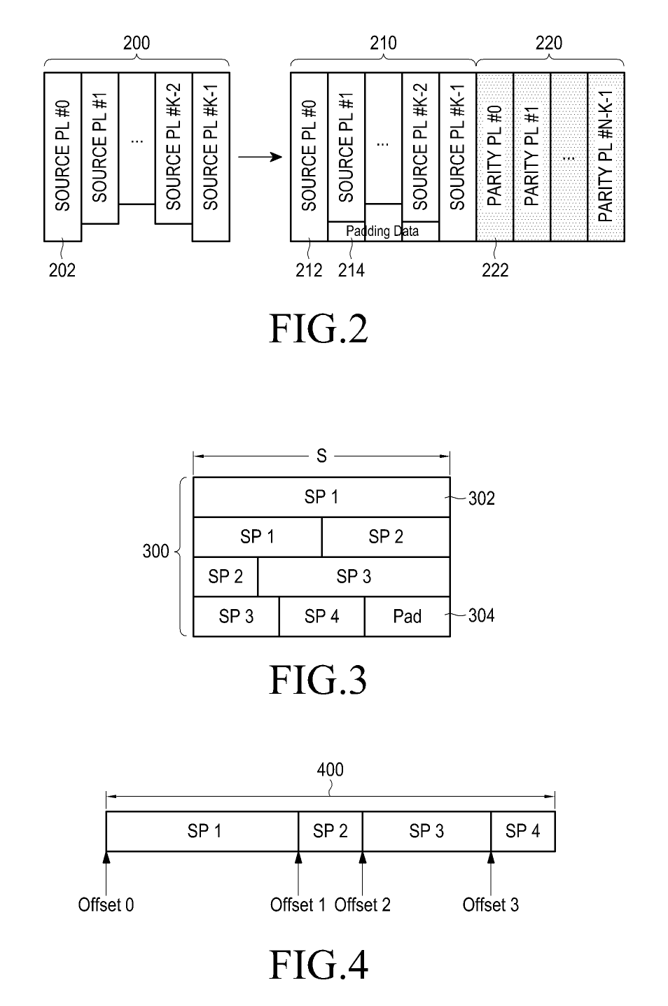

The IBG_mode1 represents an IBG mode that applies if a length of a source payload is variable. In the IBG_mode1, information blocks having sizes that are the same are generated by adding padding data to source payloads respectively. In the IBG_mode1, the number of source payloads included in a source block is equal to the number of information payloads included in an information block. In the IBG_mode1, the length of the source payload is variable, so virtual length information is needed for each of the source payloads. The IBG_mode1 will be described with reference to FIG. 2.

The IBG_mode2 represents an IBG mode that applies if a length of a source payload is variable. In the IBG_mode2, information blocks having sizes that are the same are generated by adding padding data to source payloads respectively. In the IBG_mode2, the number of source payloads included in a source block may not be equal to the number of information payloads included in an information block. In the IBG_mode2, the length of the source payload is variable, so virtual length information is needed for each of the source payloads. The IBG_mode2 will be described with reference to FIGS. 3 and 4.

FIG. 2 illustrates a process for generating a source block by an FEC packet transmission apparatus of which an operation mode is an IBG_mode1 in an MMT system according to an exemplary embodiment of the present invention.

Referring to FIG. 2, if source block 200 including K source payloads (source PLs) 202 having a variable packet size, that is, a source PL #0 to a source PL #K−1 is input for the AL-FEC encoding, an FEC packet transmission apparatus adds padding data 214 to at least some of the source payloads in order to make the source payloads equally have a predetermined length of S (for example, S=Sₘₐₓ) to configure information payloads 212 having the same length. Here, Sₘₐₓ represents a maximum length among the sizes of the source payloads. The information payloads 212 configure an information block 210.

The FEC packet transmission apparatus encodes the information block 210 according to a preset FEC code, and generates parity payloads 222 corresponding to the information payloads 212, that is, a parity payload (parity PL) #0 to a parity PL #N−K−1. The N−K parity payloads 222 configure a parity block 220. The FEC packet transmission apparatus transmits the source block 200 and the parity block 220 in a form of packets. For example, payloads of the source block 200 and the parity block 220 are carried on packets and then transferred.

In an IBG_mode1 of FIG. 2, for example, if a total amount of the padding data 214 corresponds to a size of the information block 210 after the padding, that is, 50% of Sₘₐₓ×K, 50% of the parity block 220 is added for the padding data, so that unnecessary transmission is generated. Since payloads reconstructed after an FEC decoding include the padding data, it is required to notify an FEC packet reception apparatus of actual lengths of the source payloads. If packet loss is generated in an application channel environment, a related payload itself is lost, and thus a length of data stored in the payload cannot be known, unlike a physical channel.

FIG. 3 illustrates a process for generating a source block by an FEC packet transmission apparatus of which an operation mode is an IBG_mode2 in an MMT system according to an exemplary embodiment of the present invention.

Referring to FIG. 3, input source packets 302 including SP1 to SP4 are arranged within a two-dimensional array 300 having a predetermined horizontal length of S in an order according to a predetermined rule. In the illustrated example, SP1, having a relatively long length, is arranged in an entire part in a first row of the two-dimensional array 300 and part of a front part in a second row. SP2 is arranged in part of a back part in the second row and part of a front part in a third row. SP3 is arranged in part of a back part in the third row and part of a front part in a fourth row. Finally, SP4, having a relatively short length, is arranged in a center of the fourth row. Padding data 304 occupies the remaining parts of the two-dimensional array 300 other than the parts where the source packets 302 are arranged.

Each row of the information block including the above two-dimensional array 300 is the information payload, so that K corresponding to the number of information payloads may be smaller than K′ corresponding to the number of source payloads. The FEC packet transmission apparatus encodes the information block including the two-dimensional array 300 to generate parity payloads. The IBG_mode2 using such a two-dimensional array 300 reduces the number of information payloads in comparison with the IBG_mode1 of FIG. 2, and accordingly reduces an amount of parity payloads.

FIG. 4 illustrates offset information of each payload included in a two-dimensional array, for example the two-dimensional array as shown in FIG. 3, according to an exemplary embodiment of the present invention.

Referring to FIG. 4, offset information indicating a start position of each source packet on a serialized two-dimensional array 400 is transmitted together with a source block. In FIG. 4, the offset information includes offset0, offset1, offset2 and offset3. An FEC packet reception apparatus reconfigures the two-dimensional array 400 from the offset of each source packet to perform an FEC decoding operation.

If an FEC packet transmission apparatus generates an FEC packet corresponding to an IBG_mode2 in FIG. 3 or 4, it is required to notify an FEC packet reception apparatus of actual lengths of the source PLs since payloads repaired after an FEC decoding include the padding data. If packet loss occurs in an application channel environment, a related payload itself is lost, and thus a length of data stored in the payload cannot be known, unlike a physical channel.

A process in which an FEC packet transmission apparatus notifies an FEC packet reception apparatus of a size of a payload included in a source block will be described.

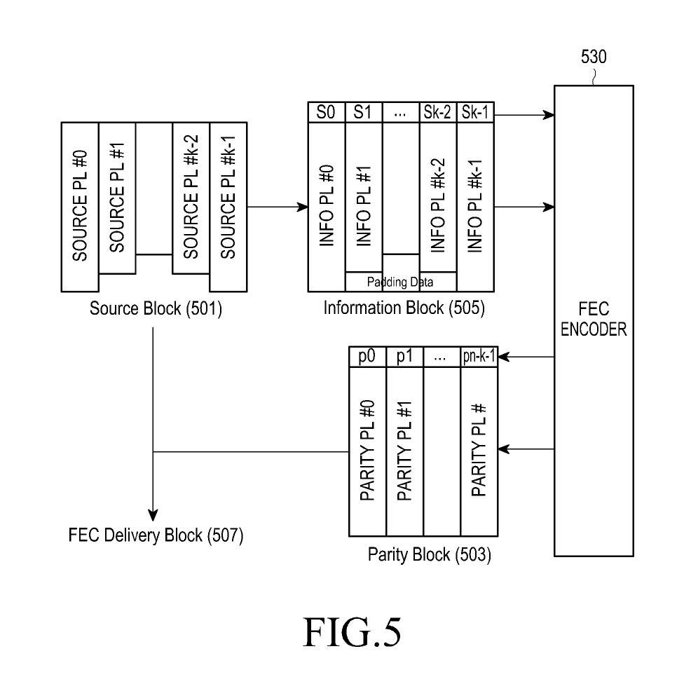

FIG. 5 schematically illustrates an operation of an FEC packet transmission apparatus of an MMT system according to an exemplary embodiment of the present invention.

Referring to FIG. 5, the FEC packet transmission apparatus fragments data desired to be transmitted into k source payloads having a length Si (i=0, 1, . . . , k−1), and generates a parity block 503 including n−k parity payloads based on a source block 501 including the k source payloads. The FEC packet transmission apparatus transmits an FEC delivery block 507 including the source block 501 and the parity block 503 to an FEC packet reception apparatus.

The FEC packet transmission apparatus generates k information payloads by adding related padding bytes to each of source payloads included in the source block 501 and generates an information block 505 including k information payloads. The FEC packet transmission apparatus generates virtual length information data including lengths Sis of source payloads. An FEC encoder 530 included in the FEC packet transmission apparatus generates the virtual length information data based on an information block 505, a parity block 503 including n−k−1 parity payloads, and parity data for the virtual length information data corresponding to a preset FEC code.

The parity block 503 and the parity data are transmitted with the source block 501 to the FEC packet reception apparatus. A controller (not illustrated in FIG. 5) may generate the virtual length information data by counting a size of data included in each of the source payloads which are input to the FEC packet transmission apparatus, or generate the virtual length information data by inputting information on a length of a source payload since the FEC packet transmission apparatus may know the length of the source payload.

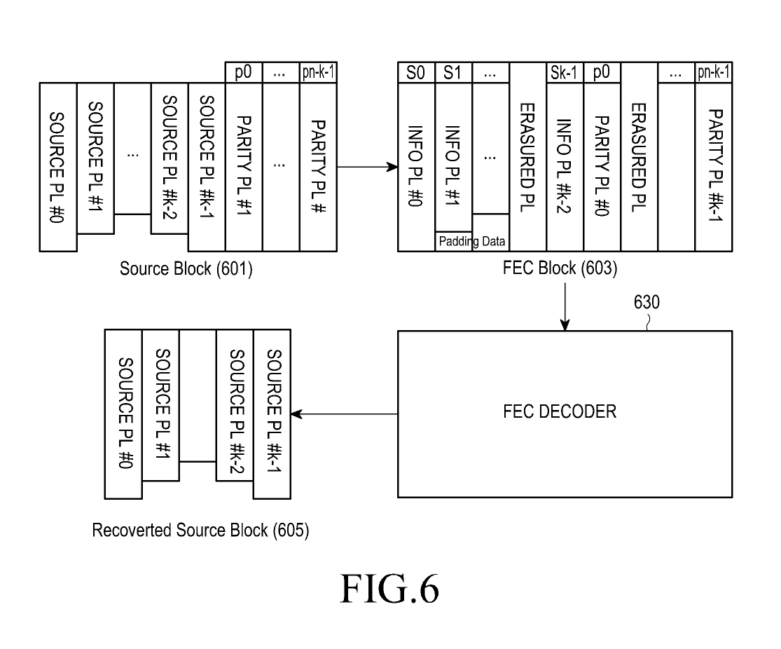

FIG. 6 schematically illustrates an operation of an FEC packet reception apparatus of an MMT system according to an exemplary embodiment of the present invention.

Referring to FIG. 6, the FEC packet reception apparatus receives an FEC delivery block including a lost packet. Since the FEC packet reception apparatus may detect length information on each of source payloads included in a source block 601 by counting a length of each of the source payloads, the FEC packet reception apparatus acquires parity data generated on FEC encoding from a received parity payload using the length information and virtual length information for the source payloads. Since the FEC packet reception apparatus may not know length information on a lost source payload, the FEC packet reception apparatus erases a part related to the lost source payload. An FEC decoder 630 included in the FEC packet reception apparatus recovers length information on lost source payloads by performing an erasure correction operation on the erased source payload.

The FEC packet reception apparatus generates an information block by adding padding data to each of received source payloads. In this case, the FEC packet reception apparatus erases an information payload corresponding to a lost source payload and recovers an FEC block 603 including information payloads by performing an erasure correction operation through the FEC decoder 630. Since the FEC packet reception apparatus may acquire a length of a source payload included in the recovered information payload from the recovered length information, the FEC packet reception apparatus outputs a recovered source block 605 including source payloads transmitted from the FEC packet transmission apparatus.

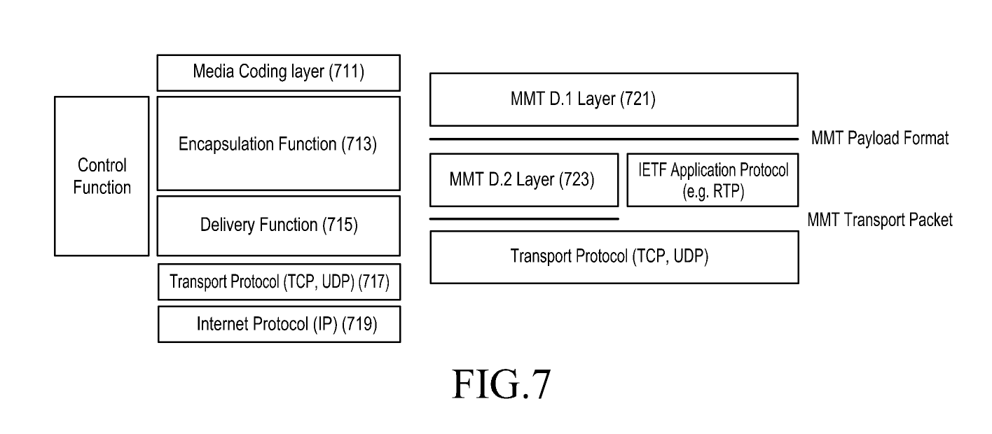

FIG. 7 schematically illustrates a structure of an MMT system and a delivery function layer according to an exemplary embodiment of the present invention.

Referring to FIG. 7, audio/video data compressed in a media coding layer 711 is packaged in a form similar to a file format and output in an encapsulation function layer (E layer) 713.

A delivery function layer 715 converts the data output from the E Layer 713 into an MMT payload format, generates an MMT transport packet by adding an MMT transport packet header to the MMT payload format, and outputs the MMT transport packet. On the other hand, the delivery function layer 715 converts the MMT payload format into an RTP packet using an RTP, and outputs the RTP packet.

The MMT transport packet or the RTP packet output from the delivery function layer 715 is converted into an IP Packet, and the IP Packet is transmitted in an IP layer 719 through a protocol layer 717 of User Datagram Protocol (UDP)/Transport Control Protocol (TCP).

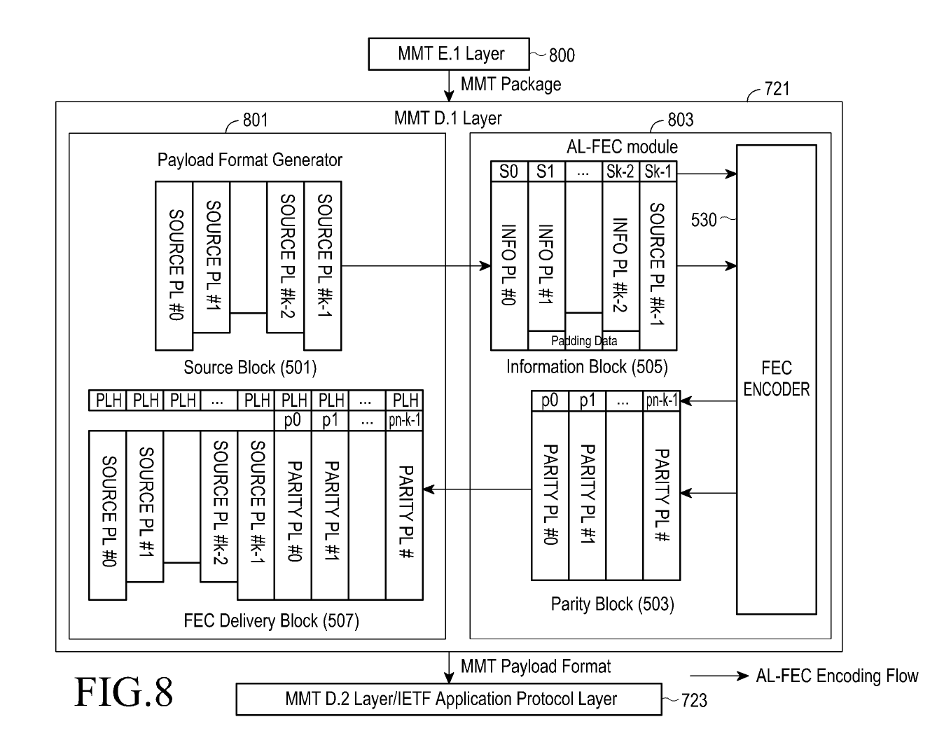

FIG. 8 schematically illustrates an AL-FEC source block encoding process performed by an FEC packet transmission apparatus of an MMT system according to an exemplary embodiment of the present invention.

Referring to FIG. 8, an MMT D.1 layer 721 receives an MMT Package (a format generated for storing Audio/Video (AV) data, file, text and the like on a storage unit or transmitting the AV data, file, text and the like) from an MMT E.1 layer, and generates a source block 501 by fragmenting the received MMT package on a preset unit basis, for example, on a source payload basis. As described above, the MMT package includes at least one MMT asset. For example, an audio asset is an MMT asset transmitting audio data, and a video asset is an MMT asset transmitting video data.

An AL-FEC module 803 generates virtual length information by counting length information Si (i=0, 1, . . . , k−1) for each of source payloads included in the source block 501, or receiving the length information Si (i=0, 1, . . . , k−1) for each of the source payloads from one of a payload format generator 801 and a controller (not illustrated in FIG. 8). The AL-FEC module 803 generates an information block 505 by adding padding data in order to make the source payloads included in the source block 501 have the same length.

An FEC encoder 530 generates parity data for virtual length information and a parity block 503 for the source block 501 by performing an FEC encoding operation based on the information block 505 and the virtual length information according to a preset FEC code, and transmits the parity data and the parity block 503 to the payload format generator 801.

The payload format generator 801 transmits an MMT payload format which is generated by adding the parity data and the parity block 503 to the source block 501 and adding a PayLoad Header (PLH) to each payload to an MMT D.2 layer or an Internet Engineering Task Force (IETF) application protocol layer 723. As described in FIG. 1, in the MMT D.2 layer or the IETF application protocol layer 723, a UDP header and an IP header are added to the MMT payload format through a transport protocol such as a UDP, and the MMT payload format to which the UDP header and the IP header are added are transmitted to an FEC packet reception apparatus.

In exemplary embodiments of the present invention, the parity data for the virtual length information is included in the parity block. However, it will be understood by those of ordinary skill in the art that the parity data is included at a preset location within an FEC delivery block including a payload format header. Here, the preset location is a location which the FEC packet transmission apparatus and the FEC packet reception apparatus have been mutually promised.

For example, the parity data may be allocated over one of a source block and a parity block within an FEC delivery block, may be allocated under one of the source block and the parity block within the FEC delivery block, may be included in PLHs for the source block, or may be included in PLHs for the parity block. The FEC packet reception apparatus has a structure similar to the FEC packet transmission apparatus in FIG. 8 and performs an operation described in FIG. 6.

For convenience, it will be assumed that the virtual length information data is included in PLHs.

An MMT payload format is expressed in Table 1.

TABLE 1

| | |
|---|---|
| payload | MMT payload (source |
| header | payload or parity payload) |

In Table 1, the source payload may be an MMT payload format or an MMT transport packet.

A payload header format for a parity payload is expressed in Table 2.

TABLE 2

payload type ( = parity payload)
sequence number
FEC_flag
block boundary info
payload size flag
FEC delivery block length : n
source block length : k
parity data for virtual lengths if payload size flag==1

A payload header format for a source payload is expressed in Table 3.

TABLE 3

payload type ( = source payload)
sequence number
FEC flag
block boundary info
payload size flag
FEC delivery block length : n
source block length : k

In Tables 2 and 3, the payload type represents a payload of a related MMT payload format. In Table 2, the payload header format is a payload header format for a parity payload, so the payload type represents the parity payload. In Table 3, the payload header format is a payload header format for a source payload, so the payload type represents the source payload.

In Tables 2 and 3, the sequence number is allocated in an ascending order or a descending order in order to indicate an order of payloads to be transmitted, so the sequence number may be used to determine whether a packet has been lost.

In Tables 2 and 3, the FEC flag indicates whether an FEC scheme has been applied. For example, if a value of the FEC flag is set to 0, a source block is transmitted without a parity payload and the FEC scheme has not been applied. If a value of the FEC flag is set to 1, a source block is transmitted with a parity block and the FEC scheme has been applied.

In Tables 2 and 3, the block boundary info represents a boundary of an FEC delivery block. A sequence number of the first source payload included in the FEC delivery block is allocated to all headers.

In Table 2, the payload size flag may indicate whether lengths of all parity payloads included in a parity block are fixed or variable. For example, if the payload size flag is implemented with 1 bit and a value of the payload size flag is set to 0, the lengths of all the parity payloads included in the parity block are fixed. If the payload size flag is implemented with 1 bit and a value of the payload size flag is set to 1, the lengths of all the parity payloads included in the parity block are variable.

If the value of the payload size flag is set to 0, the FEC packet transmission apparatus does not have to generate virtual length information data and parity data corresponding to the virtual length information data since the lengths of all the parity payloads are fixed. If the value of the payload size flag is set to 1, the FEC packet transmission apparatus generates the virtual length information data and the parity data corresponding to the virtual length information data since the lengths of all the parity payloads are variable.

As described above, since the payload size flag indicates whether the lengths of all the parity payloads included in the parity block are fixed or variable, the payload size flag may indicate an IBG mode which the MMT system uses. For example, the payload size flag may be implemented with 2 bits. In that case, the payload size flag indicates that the MMT system uses an IBG_mode0 if a value of the payload size flag is 00, that the MMT system uses an IBG_mode1 if a value of the payload size flag is 01, and that the MMT system uses an IBG_mode2 if a value of the payload size flag is 11.

In Table 3, the payload size flag may indicate whether lengths of all source payloads included in a source block are fixed or variable. For example, if the payload size flag is implemented with 1 bit and a value of the payload size flag is set to 0, the lengths of all the source payloads included in the source block are fixed. If the payload size flag is implemented with 1 bit and a value of the payload size flag is set to 1, the lengths of all the source payloads included in the source block are variable.

If the value of the payload size flag is set to 0, the FEC packet transmission apparatus does not have to generate virtual length information data and parity data corresponding to the virtual length information data since the lengths of all the source payloads are fixed. If the value of the payload size flag is set to 1, the FEC packet transmission apparatus generates the virtual length information data and the parity data corresponding to the virtual length information data since the lengths of all the source payloads are variable.

As described above, since the payload size flag indicates whether the lengths of all the source payloads included in the source block are fixed or variable, so the payload size flag may indicate an IBG mode used by the MMT system. For example, the payload size flag may be implemented with 2 bits. In that case, the payload size flag indicates that the MMT system uses an IBG_mode0 if a value of the payload size flag is 00, that the MMT system uses an IBG_mode1 if a value of the payload size flag is 01, and that the MMT system uses an IBG_mode2 if a value of the payload size flag is 11.

In Tables 2 and 3, the FEC delivery block length indicates the number of payloads included in an FEC delivery block, and the source block length indicates the number of source payloads included in a source block.

In Table 2, the parity data represents parity data. The parity data is included in Table 2 if the value of the payload size flag is set to 1 (if the payload size flag is implemented with 1 bit), and the value of the payload size flag is set to 01 or 11 (if the payload size flag is implemented with 2 bits).

In an exemplary embodiment of the present invention, a process in which virtual length information data is transmitted/received through a payload header format is described. However, it will be understood by those of ordinary skill in the art that the virtual length information data may be transmitted/received through a control message. The control message may be implemented by modifying a message which the MMT system uses or may be implemented as a new message.

In an exemplary embodiment of the present invention, a process in which a payload size flag is transmitted/received through a payload header format is described. However, it will be understood by those of ordinary skill in the art that the payload size flag may be transmitted/received through a control message. The control message may be implemented by modifying a message used by the MMT system or may be implemented as a new message.

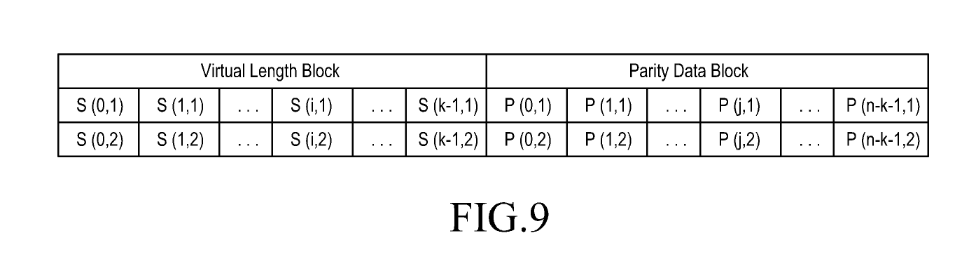

FIG. 9 schematically illustrates a structure of a virtual length block and a parity data block generated by an FEC packet transmission apparatus of an MMT system according to an exemplary embodiment of the present invention.

Referring to FIG. 9, it will be assumed that length information is 2 bytes since the 2 bytes is sufficient to cover 65000 bytes except for header information in an MMT system.

In FIG. 9, S(i,r) indicates the rth bytes among length information of the i+1th source payload included in a source block, and p(j,r) indicates the rth bytes from over or under a location of the i+1th parity payload included in a parity block (that is, a parity data block with a size in 2×(n−k) bits is allocated under or over a parity block) if the parity data block is transmitted over or under the parity block.

In an exemplary embodiment of the present invention, a case that a parity data block is generated based on a virtual length block using an FEC code identical to an FEC code which is used if a parity block is generated based on a source block is described. However, it will be understood by those of ordinary skill in the art that the present invention is not limited to the case. For example, if a parity block including 20 parity payloads is generated based on a source block including 200 source payloads, a parity data block with a size in 16×20 bits may be generated based on a virtual length block with a size in 16×200 bits by applying the same FEC structure, or a parity data block with a size in 16×40 bits may be generated by applying a twofold increase in a parity generation rate. In this case, it is desirable that the parity data block with the size in 16×40 bits is located over or under a parity block by rearranging the parity data block with the size in 16×40 bits as a parity data block with a size in 32×20 bits. This is why the FEC packet reception apparatus helps to guarantee a stable process by notifying an upper layer of a length of a lost source payload after repairing information on a length of a source payload even if the source block is not repaired.

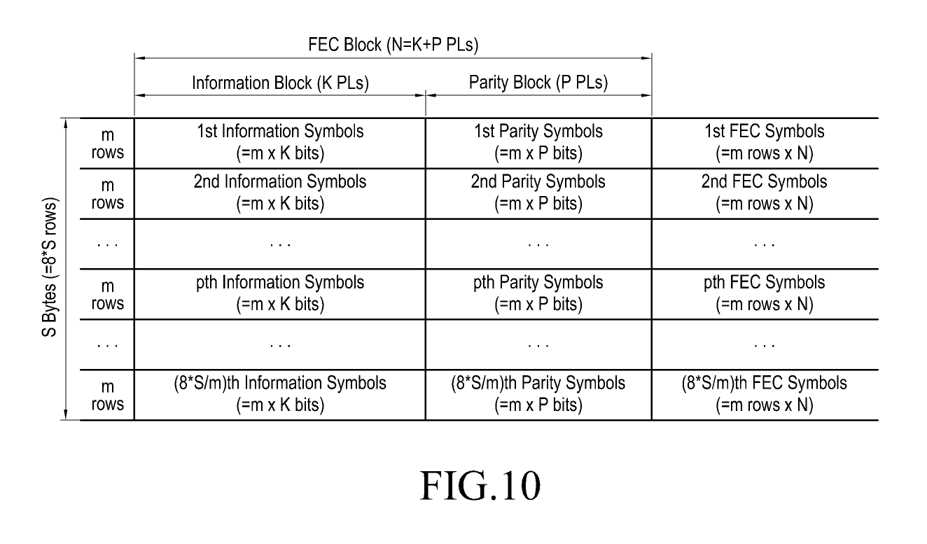

FIG. 10 schematically illustrates a structure of an information block and a parity block generated by an FEC packet transmission apparatus of an MMT system according to an exemplary embodiment of the present invention.

Referring to FIG. 10, if m=1, K=200, and an FEC (220,200) code is used for generating a parity block, an FEC packet reception apparatus may repair up to a maximum of 20 packets even if the FEC (220,200) code is an ideal code.

However, if a parity data block is generated using an FEC (240,200) code, the FEC packet reception apparatus may detect a length of a source payload even if a lost source block is not repaired since the FEC packet reception apparatus may repair R packets. Here, R is greater than or equal to 20. In FIG. 10, an FEC block including a parity block generated based on an information block including K information payloads is illustrated. The information block includes information symbols including m rows, parity symbols are generated based on each of the information symbols according to a preset FEC code, and an FEC frame including the information symbols and the parity symbols is generated (m is an positive integer).

For parity data which is generated based on virtual length information data, a parity data block may be generated based on a virtual length block by using the same FEC code and the same scheme used for generating a parity block based on an information block.

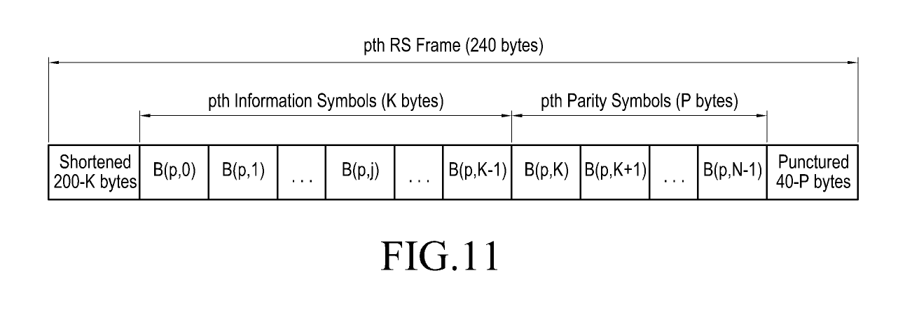

FIG. 11 schematically illustrates a structure of an RF frame, which uses a Reed-Solomon (RS) (240,200) code over a GF (2̂8) if m is 8 (m=8), generated by an FEC packet transmission apparatus of an MMT system according to an exemplary embodiment of the present invention.

Referring to FIG. 11, the pth byte row of an information block including K payloads becomes the pth information symbols K bytes, the pth RS frame is generated by generating parity bytes 40 bytes after 200-K bytes are padded with 00h and an FEC encoding operation is performed. Finally, information symbols K bytes and parity symbols P bytes are transmitted after the first 200-K padding bytes are shortened and the last 40-P bytes are punctured.

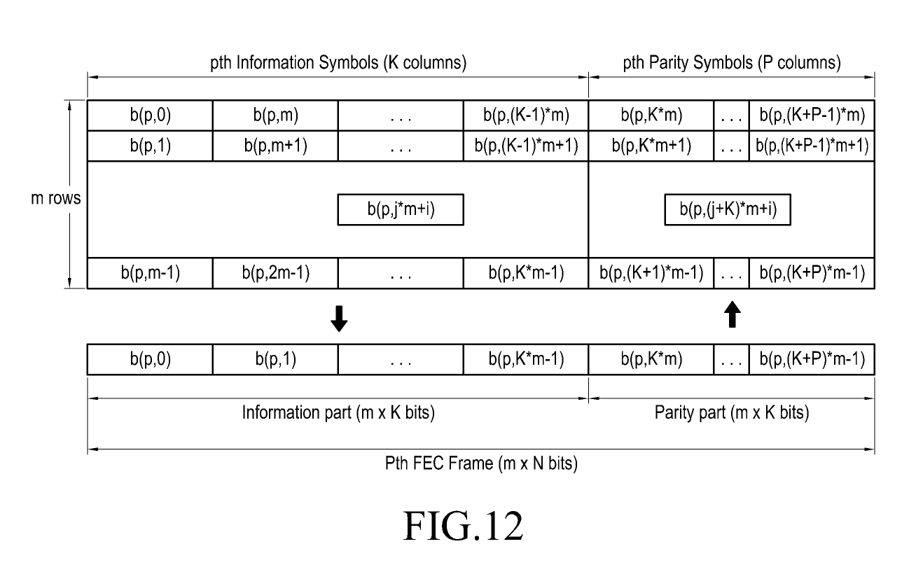

FIG. 12 schematically illustrates a structure of a Low Density Parity Check frame, which uses a (m×(K+P), m×K) Low Density Parity Check (LDPC) code over a GF (2̂8), generated by an FEC packet transmission apparatus of an MMT system according to an exemplary embodiment of the present invention.

Referring to FIG. 12, the pth m row(s) of an information block including K payloads becomes the pth information symbols (m×K bits), the pth LDPC frame is generated using m×P parity bits, and the m×P parity bits are generated as parity symbols (m is an positive integer).

In FIG. 12, if m is greater than 1, an index is allocated from top to bottom and from left to right. However, it will be understood by those of ordinary skill in the art that the index may be allocated from bottom to top and from right to left.

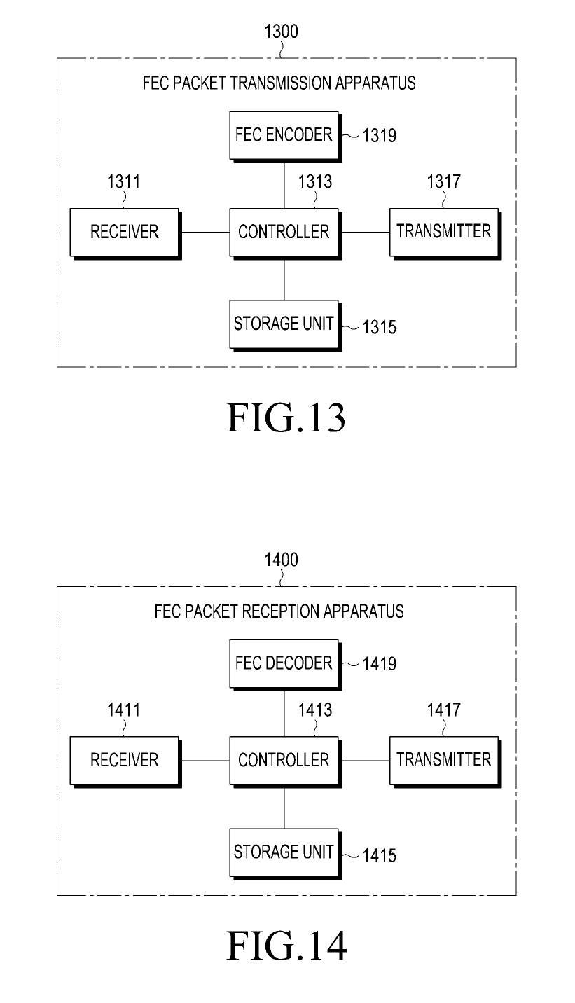

FIG. 13 is a block diagram schematically illustrating an internal structure of an FEC packet transmission apparatus in an MMT system according to an exemplary embodiment of the present invention.

Referring to FIG. 13, an FEC packet transmission apparatus 1300 includes a receiver 1311, a controller 1313, a storage unit 1315, a transmitter 1317 and an FEC encoder 1319.

The controller 1313 controls operations of the FEC packet transmission apparatus 1300. More specially, the controller 1313 controls the FEC packet transmission apparatus 1300 to transmit information indicating whether lengths of all source payloads included in a source block are the same, and indicating an IBG mode which an MMT system uses. The operation of transmitting the information indicating whether the lengths of all the source payloads included in the source block are the same, and indicating the IBG mode which the MMT system uses is performed in the manner described before with reference to FIGS. 1 to 12 and Tables 1 to 3, so the detailed description will be omitted herein.

The receiver 1311 receives messages under the control of the controller 1313.

The storage unit 1315 stores the messages received by the receiver 1311 and data required for an operation of the FEC packet transmission apparatus 1300.

The transmitter 1317 transmits messages, FEC packets, and the like under the control of the controller 1313.

The FEC encoder 1319 performs an FEC encoding operation corresponding to a preset FEC encoding scheme under the control of the controller 1313.

While the receiver 1311, the controller 1313, the storage unit 1315, the transmitter 1317, and the FEC encoder 1319 are shown in FIG. 13 as separate units, it is to be understood that this is for merely convenience of description. In other words, the receiver 1311, the controller 1313, the storage unit 1315, the transmitter 1317 and the FEC encoder 1319 may be incorporated into a single unit.

FIG. 14 is a block diagram schematically illustrating an internal structure of an FEC packet reception apparatus in an MMT system according to an exemplary embodiment of the present invention.

Referring to FIG. 14, an FEC packet reception apparatus 1400 includes a receiver 1411, a controller 1413, a storage unit 1415, a transmitter 1417 and an FEC decoder 1419.

The controller 1413 controls operations of the FEC packet reception apparatus 1400. More specially, the controller 1413 controls the FEC packet reception apparatus 1400 to receive information indicating whether lengths of all source payloads included in a source block are the same, and indicating an IBG mode which an MMT system uses. The operation of receiving the information indicating whether the lengths of all the source payloads included in the source block are the same, and indicating the IBG mode which the MMT system uses is performed in the manner described before with reference to FIGS. 1 to 12 and Tables 1 to 3, so the detailed description will be omitted herein.

The receiver 1411 receives messages and FEC packets under the control of the controller 1413.

The storage unit 1415 stores the messages and the FEC packets received by the receiver 1411 and data required for an operation of the FEC packet reception apparatus 1400.

The transmitter 1417 transmits messages under the control of the controller 1413.

The FEC decoder 1419 performs an FEC decoding operation corresponding to an FEC encoding scheme used in an FEC packet transmission apparatus under the control of the controller 1413.

While the receiver 1411, the controller 1413, the storage unit 1415, the transmitter 1417 and the FEC decoder 1419 are shown in FIG. 14 as separate units, it is to be understood that this is for merely convenience of description. In other words, the receiver 1411, the controller 1413, the storage unit 1415, the transmitter 1417 and the FEC decoder 1419 may be incorporated into a single unit.

Meanwhile, though not described in any FIGs., each of the entities which join an operation of transmitting an FEC packet in an MMT system according to exemplary embodiments of the present invention include a transmitter, a receiver, a storage unit, a controller, and an FEC encoder for performing a related operation according to exemplary embodiments of the present invention. However, it will be understood by those of ordinary skill in the art that the transmitter, the receiver, the storage unit, the controller and the FEC encoder may be incorporated into a single unit.

Meanwhile, though not described in any FIGs, each of the entities which join an operation of receiving an FEC packet in an MMT system according to exemplary embodiments of the present invention includes a transmitter, a receiver, a storage unit, a controller, and an FEC decoder for performing a related operation according to exemplary embodiments of the present invention. However, it will be understood by those of ordinary skill in the art that the transmitter, the receiver, the storage unit, the controller and the FEC decoder may be incorporated into a single unit.

As is apparent from the foregoing description, exemplary embodiments of the present invention enable FEC packet transmission/reception for notifying a size of a packet before padding data is included in a mobile communication system. Exemplary embodiments of the present invention enable FEC packet transmission/reception for notifying a size of a packet before padding data is included through AL-FEC signaling information in a mobile communication system. Exemplary embodiments of the present invention enable FEC packet transmission/reception for generating a source block corresponding to an IBG mode in a mobile communication system. Exemplary embodiments of the present invention enable FEC packet transmission/reception for notifying a size of a payload of a source block generated corresponding to an IBG mode in a mobile communication system.

While the invention has been shown and described with reference to certain exemplary embodiments thereof, it will be understood by those skilled in the art that various changes in form and details may be made therein without departing from the spirit and scope of the invention as defined by the appended claims and their equivalents.

What is claimed is:

1. A method for transmitting a Forward Error Correction (FEC) packet by an FEC packet transmission apparatus in a mobile communication system, the method comprising:
transmitting an FEC delivery block to an FEC packet reception apparatus,
wherein the FEC delivery block includes K source payloads and P parity payloads, each of the K source payloads and the P parity payloads includes a payload header, and each of the payload headers includes length information related to a length of a related payload.

2. The method as claimed in claim 1, wherein the length information represents information indicating whether lengths of the K source payloads are fixed or variable if the related payload is a source payload.

3. The method as claimed in claim 1, wherein the length information indicates whether lengths of the P parity payloads are fixed or variable if the related payload is a parity payload.

4. The method as claimed in claim 3, wherein a payload header included in the related payload further includes parity data generated according to virtual length information data including the lengths of the P parity payloads if the length information indicates that the lengths of the P parity payloads are variable.

5. The method as claimed in claim 1, wherein the length information represents an Information Block Generation (IBG) mode used in the mobile communication system if the related payload is a source payload, and the IBG mode indicates whether lengths of the K source payloads are fixed or variable.

6. The method as claimed in claim 1, wherein the length information represents an Information Block Generation (IBG) mode used in the mobile communication system if the related payload is a parity payload, and the IBG mode includes an IBG_mode0 indicating whether lengths of the K source payloads are fixed, an IBG_mode1 indicating that the lengths of the K source payloads are variable and at least one of the K source payloads includes padding data, and an IBG_mode2 indicating whether the lengths of the K source payloads are variable.

7. The method as claimed in claim 6, wherein the IBG_mode1 indicates that K information blocks are generated by adding padding data to at least one of the K source payloads, the IBG_mode2 indicates that the K information blocks or L information blocks are generated by arranging the K source payloads in a two-dimension array, and L is less than K.

8. The method as claimed in claim 1, wherein the length information represents an Information Block Generation (IBG) mode used in the mobile communication system if the related payload is a parity payload, and the IBG mode indicates whether lengths of the P parity payloads are fixed or variable.

9. The method as claimed in claim 8, wherein a payload header included in the related payload further includes parity data generated according to virtual length information data including the lengths of the P parity payloads if the IBG mode indicates that the lengths of the P parity payloads are variable.

10. The method as claimed in claim 1, wherein the length information represents an Information Block Generation (IBG) mode used in the mobile communication system if the related payload is a parity payload, and the IBG mode includes an IBG_mode0 indicating whether lengths of the P parity payloads are fixed, an IBG_mode1 indicating that the lengths of the P parity payloads are variable and at least one of the P parity payloads includes padding data, and an IBG_mode2 indicating whether the lengths of the P parity payloads are variable.

11. The method as claimed in claim 10, wherein the IBG_mode1 indicates that P parity blocks are generated by adding padding data to at least one of the P parity payloads, the IBG_mode2 indicates that the P parity blocks or M parity blocks are generated by arranging the P parity payloads in a two-dimension array, and M is less than P.

12. The method as claimed in claim 10, wherein a payload header included in the related payload further includes parity data generated according to virtual length information data including the lengths of the P parity payloads if the IBG mode is one of the IBG_mode1 and the IBG_mode2.

13. A method for receiving a Forward Error Correction (FEC) packet by an FEC packet reception apparatus in a mobile communication system, the method comprising:
receiving an FEC delivery block from an FEC packet transmission apparatus,
wherein the FEC delivery block includes K source payloads and P parity payloads, each of the K source payloads and the P parity payloads includes a payload header, and each of the payload headers includes length information related to a length of a related payload.

14. The method as claimed in claim 13, wherein the length information represents information indicating whether lengths of the K source payloads are fixed or variable if the related payload is a source payload.

15. The method as claimed in claim 13, wherein the length information indicates whether lengths of the P parity payloads are fixed or variable if the related payload is a parity payload.

16. The method as claimed in claim 15, wherein a payload header included in the related payload further includes parity data generated according to virtual length information data including the lengths of the P parity payloads if the length information indicates that the lengths of the P parity payloads are variable.

17. The method as claimed in claim 13, wherein the length information represents an Information Block Generation (IBG) mode used in the mobile communication system if the related payload is a source payload, and the IBG mode indicates whether lengths of the K source payloads are fixed or variable.

18. The method as claimed in claim 13, wherein the length information represents an Information Block Generation (IBG) mode used in the mobile communication system if the related payload is a parity payload, and the IBG mode includes an IBG_mode0 indicating whether lengths of the K source payloads are fixed, an IBG_mode1 indicating that the lengths of the K source payloads are variable and at least one of the K source payloads includes padding data, and an IBG_mode2 indicating whether the lengths of the K source payloads are variable.

19. The method as claimed in claim 18, wherein the IBG_mode1 indicates that K information blocks are generated by adding padding data to at least one of the K source payloads, the IBG_mode2 indicates that the K information blocks or L information blocks are generated by arranging the K source payloads in a two-dimension array, and L is less than K.

20. The method as claimed in claim 13, wherein the length information represents an Information Block Generation (IBG) mode used in the mobile communication system if the related payload is a parity payload, and the IBG mode indicates whether lengths of the P parity payloads are fixed or variable.

21. The method as claimed in claim 20, wherein a payload header included in the related payload further includes parity data generated according to virtual length information data including the lengths of the P parity payloads if the IBG mode indicates that the lengths of the P parity payloads are variable.

22. The method as claimed in claim 13, wherein the length information represents an Information Block Generation (IBG) mode used in the mobile communication system if the related payload is a parity payload, and the IBG mode includes an IBG_mode0 indicating whether lengths of the P parity payloads are fixed, an IBG_mode1 indicating that the lengths of the P parity payloads are variable and at least one of the P parity payloads includes padding data, and an IBG_mode2 indicating whether the lengths of the P parity payloads are variable.

23. The method as claimed in claim 22, wherein the IBG_mode1 indicates that P parity blocks are generated by adding padding data to at least one of the P parity payloads, the IBG_mode2 indicates that the P parity blocks or M parity blocks are generated by arranging the P parity payloads in a two-dimension array, and M is less than th P.

24. The method as claimed in claim 22, wherein a payload header included in the related payload further includes parity data generated according to virtual length information data including the lengths of the P parity payloads if the IBG mode is one of the IBG_mode1 and the IBG_mode2.

25. A Forward Error Correction (FEC) packet transmission apparatus in a mobile communication system, the apparatus comprising:
a transmitter for transmitting an FEC delivery block to an FEC packet reception apparatus,
wherein the FEC delivery block includes K source payloads and P parity payloads, each of the K source payloads and the P parity payloads includes a payload header, and each of the payload headers includes length information related to a length of a related payload.

26. The FEC packet transmission apparatus as claimed in claim 25, wherein the length information represents information indicating whether lengths of the K source payloads are fixed or variable if the related payload is a source payload.

27. The FEC packet transmission apparatus as claimed in claim 25, wherein the length information indicates whether lengths of the P parity payloads are fixed or variable if the related payload is a parity payload.

28. The FEC packet transmission apparatus as claimed in claim 27, wherein a payload header included in the related payload further includes parity data generated according to virtual length information data including the lengths of the P parity payloads if the length information indicates that the lengths of the P parity payloads are variable.

29. The FEC packet transmission apparatus as claimed in claim 25, wherein the length information represents an Information Block Generation (IBG) mode used in the mobile communication system if the related payload is a source payload, and the IBG mode indicates whether lengths of the K source payloads are fixed or variable.

30. The FEC packet transmission apparatus as claimed in claim 25, wherein the length information represents an Information Block Generation (IBG) mode used in the mobile communication system if the related payload is a parity payload, and the IBG mode includes an IBG_mode0 indicating whether lengths of the K source payloads are fixed, an IBG_mode1 indicating that the lengths of the K source payloads are variable and at least one of the K source payloads includes padding data, and an IBG_mode2 indicating whether the lengths of the K source payloads are variable.

31. The FEC packet transmission apparatus as claimed in claim 30, wherein the IBG_mode1 indicates that K information blocks are generated by adding padding data to at least one of the K source payloads, the IBG_mode2 indicates that the K information blocks or L information blocks are generated by arranging the K source payloads in a two-dimension array, and L is less than K.

32. The FEC packet transmission apparatus as claimed in claim 25, wherein the length information represents an Information Block Generation (IBG) mode used in the mobile communication system if the related payload is a parity payload, and the IBG mode indicates whether lengths of the P parity payloads are fixed or variable.

33. The FEC packet transmission apparatus as claimed in claim 32, wherein a payload header included in the related payload further includes parity data generated according to virtual length information data including the lengths of the P parity payloads if the IBG mode indicates that the lengths of the P parity payloads are variable.

34. The FEC packet transmission apparatus as claimed in claim 25, wherein the length information represents an Information Block Generation (IBG) mode used in the mobile communication system if the related payload is a parity payload, and the IBG mode includes an IBG_mode0 indicating whether lengths of the P parity payloads are fixed, an IBG_mode1 indicating that the lengths of the P parity payloads are variable and at least one of the P parity payloads includes padding data, and an IBG_mode2 indicating whether the lengths of the P parity payloads are variable.

35. The FEC packet transmission apparatus as claimed in claim 34, wherein the IBG_mode1 indicates that P parity blocks are generated by adding padding data to at least one of the P parity payloads, the IBG_mode2 indicates that the P parity blocks or M parity blocks are generated by arranging the P parity payloads in a two-dimension array, and M is less than P.

36. The FEC packet transmission apparatus as claimed in claim 34, wherein a payload header included in the related payload further includes parity data generated according to virtual length information data including the lengths of the P parity payloads if the IBG mode is one of the IBG_mode1 and the IBG_mode2.

37. A Forward Error Correction (FEC) packet reception apparatus in a mobile communication system, the apparatus comprising:
a receiver for receiving an FEC delivery block from an FEC packet transmission apparatus,
wherein the FEC delivery block includes K source payloads and P parity payloads, each of the K source payloads and the P parity payloads includes a payload header, and each of the payload headers includes length information related to a length of a related payload.

38. The FEC packet reception apparatus as claimed in claim 37, wherein the length information represents information indicating whether lengths of the K source payloads are fixed or variable if the related payload is a source payload.

39. The FEC packet reception apparatus as claimed in claim 37, wherein the length information indicates whether lengths of the P parity payloads are fixed or variable if the related payload is a parity payload.

40. The FEC packet reception apparatus as claimed in claim 39, wherein a payload header included in the related payload further includes parity data generated according to virtual length information data including the lengths of the P parity payloads if the length information indicates that the lengths of the P parity payloads are variable.

41. The FEC packet reception apparatus as claimed in claim 37, wherein the length information represents an Information Block Generation (IBG) mode used in the mobile communication system if the related payload is a source payload, and the IBG mode indicates whether lengths of the K source payloads are fixed or variable.

42. The FEC packet reception apparatus as claimed in claim 37, wherein the length information represents an Information Block Generation (IBG) mode used in the mobile communication system if the related payload is a parity payload, and the IBG mode includes an IBG_mode0 indicating whether lengths of the K source payloads are fixed, an IBG_mode1 indicating that the lengths of the K source payloads are variable and at least one of the K source payloads includes padding data, and an IBG_mode2 indicating whether the lengths of the K source payloads are variable.

43. The FEC packet reception apparatus as claimed in claim 42, wherein the IBG_mode1 indicates that K information blocks are generated by adding padding data to at least one of the K source payloads, the IBG_mode2 indicates that the K information blocks or L information blocks are generated by arranging the K source payloads in a two-dimension array, and L is less than K.

44. The FEC packet reception apparatus as claimed in claim 37, wherein the length information represents an Information Block Generation (IBG) mode used in the mobile communication system if the related payload is a parity payload, and the IBG mode indicates whether lengths of the P parity payloads are fixed or variable.

45. The FEC packet reception apparatus as claimed in claim 44, wherein a payload header included in the related payload further includes parity data generated according to virtual length information data including the lengths of the P parity payloads if the IBG mode indicates that the lengths of the P parity payloads are variable.

46. The FEC packet reception apparatus as claimed in claim 37, wherein the length information represents an Information Block Generation (IBG) mode used in the mobile communication system if the related payload is a parity payload, and the IBG mode includes an IBG_mode0 indicating whether lengths of the P parity payloads are fixed, an IBG_mode1 indicating that the lengths of the P parity payloads are variable and at least one of the P parity payloads includes padding data, and an IBG_mode2 indicating whether the lengths of the P parity payloads are variable.

47. The FEC packet reception apparatus as claimed in claim 46, wherein the IBG_mode1 indicates that P parity blocks are generated by adding padding data to at least one of the P parity payloads, the IBG_mode2 indicates that the P parity blocks or M parity blocks are generated by arranging the P parity payloads in a two-dimension array, and M is less than P.

48. The FEC packet reception apparatus as claimed in claim 46, wherein a payload header included in the related payload further includes parity data generated according to virtual length information data including the lengths of the P parity payloads if the IBG mode is one of the IBG_mode1 and the IBG_mode2.
